(19) United States
(12) Patent Application Publication
(10) Pub. No.: US 2009/0107846 A1
(43) Pub. Date: Apr. 30, 2009

(54) Method and apparatus to prewet wafer surface for metallization from electrolyte solutions

(75) Inventors: Yue Ma, Shanghai (CN); David Wang, Shanghai (CN)

Correspondence Address: LERNER, DAVID, LITTENBERG,;KRUMHOLZ & MENTLIK, 600 SOUTH AVENUE WEST, WESTFIELD, NJ, 07090, US

(73) Assignee: ACM Research (Shanghai) Inc., Shanghai (CN)

(21) Appl. No.: 12/005,538

(22) Filed: Dec. 27, 2007

Related U.S. Application Data
(63) Continuation of application No. PCT/CN2007/070980, filed on Oct. 30, 2007.

(51) Int. Cl. C25D 5/02; H01L 21/02; C23C 16/00; C25D 17/00

(52) U.S. Cl. 205/123; 205/118; 118/728; 204/242

(57) ABSTRACT

The present invention improves the wetting between electrolyte and the wafer surface when they are put into contact by pre-implementing an adsorbed liquid layer on the entire front surface of the wafer just prior to the plating process. The pre-implementing adsorbed liquid layer is realized by transporting vaporized liquid molecules from vapor phase at elevated temperature (relative to wafer) and condensing them onto wafer surface.

### FIELD

The present invention relates to wafer surface wetting for metallization, more particularly, relates to pre-wetting wafer surfaces.

### BACKGROUND

Advanced interconnections of ultra large scale integrated (ULSI) circuits are fabricated in part by electrochemically or chemically (also known as “electrolessly”) depositing metallic materials, typically copper, onto wafer surface from one or more electrolyte solutions. The deposition process, beginning with a dry wafer immersing into an electrolyte bath, or with sprays of an electrolyte solution onto a dry wafer, may encounter several problems. One severe problem is the incomplete wetting of electrolyte on the wafer surface to be deposited, for that no deposition occurs in areas where electrolyte is not in contact with the wafer surface. The wetting related defects formed by this mechanism, often manifest as pits on deposited films and large voids or miss-filled segments in vias and trenches, are known to cause appreciable number of unit devices useless.

The incomplete wetting between electrolyte and the wafer is a surface phenomenon and can be results of many process parameters that affect the surface properties of the electrolyte and the wafer. To name a few, the compatibility between the wafer surface and the electrolyte that contain various types of the organic additives, the environment the wafer is exposed to prior to electroplating or electroless plating, the age of the plating electrolyte, the queue time between the current deposition step and the previous step, which is either implementing a thin metal layer or polishing to expose both metal and dielectric partitions, in the process flow. The queue time is especially important because oxidation of wafer surface during this time significantly changes the surface properties of the wafer.

One method to improve wetting for electroplating of copper is to implement a pre-wetting station on an electrochemical deposition equipment, as disclosed by US 2004/0069644, and US 2007/7223323. According to this method, a wafer is first wetted in a spin-rinse-dry (SRD) module with de-ionized wafer (DIW). A combination of spin RPM and DIW flow rates is required to improve water coverage on the wafer surface. After pre-wetting, the wafer surface is presumably to carry a thin layer of wafer when it immerses into a plating electrolyte solution. Adding pre-wetting stations to an integrated processing tool increases the overall footprint and requires lager clean room space for such an equipment to be installed.

Another method to create such a pre-wetting layer is to use an in-situ DIW rinse nozzle within the plating process module. According to this method, DIW is injected onto wafer surface while it is held on a spinning wafer chucking device facing to the plating electrolyte solution. Centrifugal force keeps DIW on the spinning wafer surface from falling into the electrolyte solution. US 2006/7146994 has disclosed such a method. This method does not require additional space, thereby the overall tool footprint unchanged; however, it is less robust as a small misalignment of DIW nozzle can lead to DIW being injected into electrolyte solution.

Both methods have three inherent problems: (1) the layer of water that each wafer carries into the electrolyte solution causes global dilution of plating bath in a high volume factory, thereby altering the pre-set process conditions, (2) the layer of water that a wafer carries into the electrolyte solution causes local dilution near the wafer surface, especially in DIW-occupied via and trench features that are to be metallized, and results voids and miss-filled features after plating, and (3) longer overall process time. It is well understood that a typical SRD process leaves a layer of water of micrometers thickness on wafer surface, as the viscous resistance to wafer flow in a thin layer is too high (inversely proportional to the cube of its thickness) for it to be spun off. The thickness of the wafer layer can be reduced by allowing evaporation; however, more process time must be added and the overall equipment throughput surfers further. Consistent evaporation process for every wafer is difficult to achieve as robot movement and pick-up/drop-off priority in an integrated equipment impacts both evaporation conditions and time.

Yet another method is to modify the plating electrolyte by adding wetting enhancement agents, typically a surfactant or a group of surfactants to lower the surface tension of the electrolyte, as disclosed in US 2004/6776893. An alternation is to pre-treat wafer surface with liquid containing these wetting agents in a separate module prior to exposing the wafer to the plating electrolyte, as disclosed in U.S. Pat. No. 6,875,260. This type of methods increase the level of processing complexity and significantly adds costs for process characterization and monitoring. As the feature size continues to shrink, pre-wetting various wafer surfaces by displacing gas in nanometer scale via trench features with a viscous liquid, as in all three methods mentioned above, is ever challenging.

### SUMMARY OF INVENTION

The present invention improves the wetting between electrolyte and the wafer surface when they are put into contact by pre-implementing an adsorbed liquid layer on the entire front surface of the wafer just prior to the plating process. The pre-implementing adsorbed liquid layer is realized by condensing liquid molecules from vapor phase at elevated temperature (relative to wafer) onto wafer surface.

Pre-wetting is completed by transporting of liquid molecules supplied by a source constantly generating its vapor, through gaseous phase, followed by condensation, instead of using a viscous liquid to displace the gas covering the front side of the wafer.

Vapor delivery onto wafer surface is done by flowing vapor through a nozzle that is either stationary or in motion relative to wafer. And vapor is generated by heating the liquid in a vessel with controlled pressure.

Vaporized liquid molecules penetrate into small features by vapor convection and diffusion, which is much quicker compared to liquid penetration that is also governed by its wetting behavior, and is independent of solid surface properties; thus the time needed to complete vapor coverage on various wafer surfaces is the same.

### BRIEF DESCRIPTION OF DRAWINGS

FIG. 1a is a flowchart of the wafer surface pre-wetting process according to one embodiment of the present invention;

FIG. 1b is a flowchart of the wafer surface pre-wetting process according to another embodiment of the present invention;

FIG. 2 is a schematic view of the wafer surface pre-wetting apparatus according to one embodiment of the present invention.

### DETAILED DESCRIPTION OF THE EMBODIMENTS

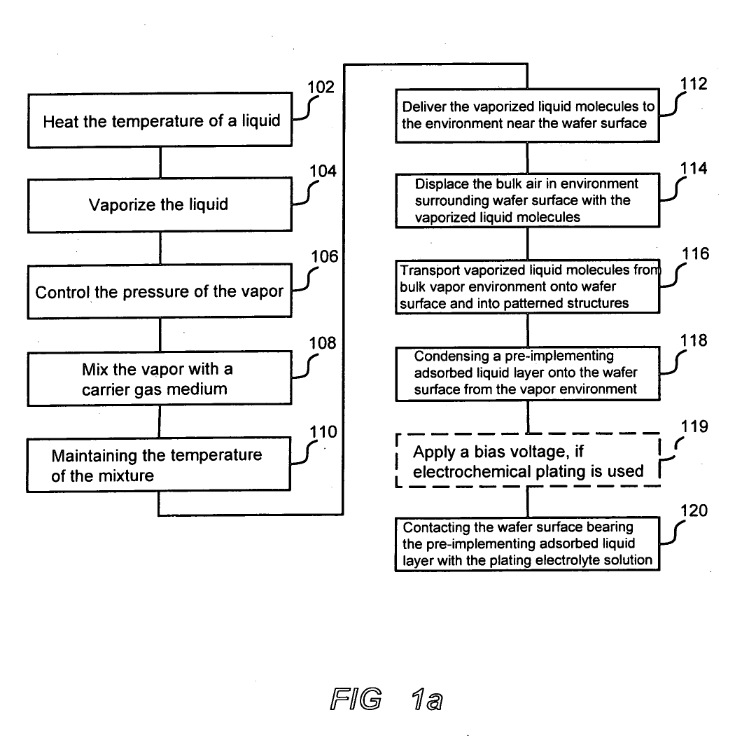

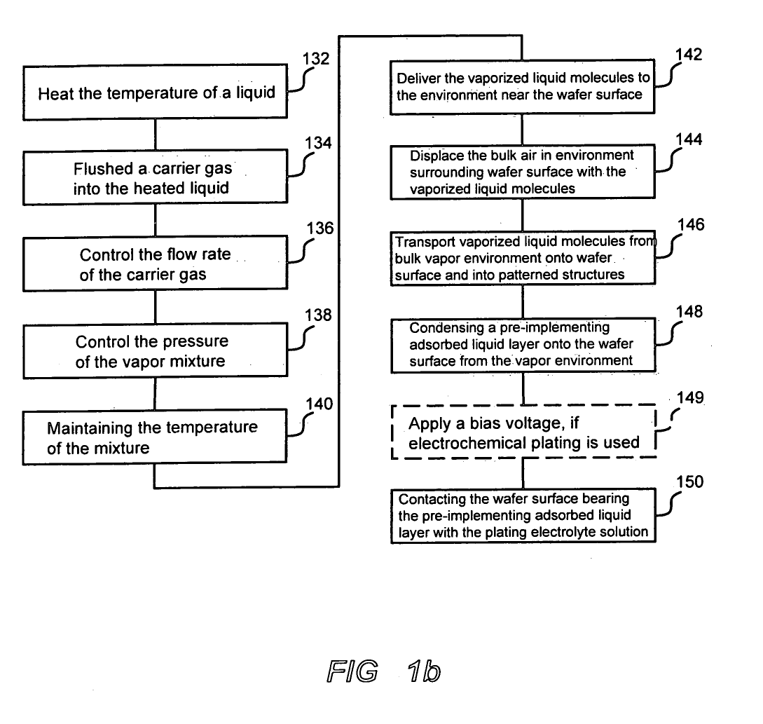

FIG. 1a shows the process for pre-wetting wafer surface for metallization. A liquid, such as de-ionized water, which will be used to form the pre-implementing adsorbed liquid layer will be heated (as shown in step 102) to a predetermined temperature. As in one embodiment, the liquid temperature will be elevated to the range between 35° C. to 170° C. After elevating to the predetermined temperature, the liquid is then be vaporized (as shown in step 104). Vaporizing the liquid can be done by either flash evaporation or by flushing the carrier gas through the liquid. When vaporizing the liquid, the pressure of the vapor is controlled (as shown in step 106). The partial pressure of the vaporized liquid is monitored by a sensor. Before the liquid molecules is delivered to the surface of the wafer, the vapor containing the liquid molecules will be mixed with a carrier gas medium, such as air, N₂, He, and Ar (as shown in step 108). While mixing the liquid molecules with the carrier gas medium, the temperature of the obtained mixture is maintained at a predetermined range (as shown in step 110), so that the pre-implementing adsorbed liquid layer formed at elevated temperature will have lower surface tension than that formed at room temperature. In the next steps vaporized liquid molecules will be transported onto the surface of the wafer, where they will condense and form a thin layer. According to FIG. 1, in step 112, the mixture of vaporized liquid molecules and carrier gas are delivered to the environment near the wafer surface. And in step 114, the bulk air in environment surrounding wafer surface is displaced with the mixture of vaporized liquid molecules and carrier gas delivered in step 112. In step 116, vaporized liquid molecules are transported from bulk vapor environment into patterned structures on the surface of the wafer. In one embodiment, transporting of the vaporized liquid molecules into the patterned features of vias, trenches and dual damascenes on the wafer surface is realized by a combination of gas phase convection and diffusion. Then, in step 118, a pre-implementing liquid layer is formed on the entire wafer front surface by multiplayer adsorption of the vaporized liquid molecules from the vapor environment. In one embodiment, condensing of the vaporized liquid molecules can be done selectively when the wafer surface having partitions of different free surface energy, and the selective condensation of the pre-implementing adsorbed liquid layer on surfaces with higher surface energy triggers selective nucleation in the subsequent metallization process. The thickness of the pre-implementing adsorbed liquid layer is typically on the scale of nanometers, orders of magnitude thinner than the pre-wetting liquid layer formed hydrodynamically by rinse and spin, which is used in prior art, whose thickness is usually in the range of tens of micrometers. In one embodiment, the thickness of the pre-implementing adsorbed liquid layer formed by multilayer adsorption of the vaporized molecules on the wafer surface is controlled by a plurality of factors, such as: the content of the vaporized liquid molecules in the environment surrounding the wafer surface, the temperature difference between the vapor and the wafer surface, the surface energy, and the heat of adsorption. In one embodiment, when the temperature difference between the vapor and the wafer surface is not significantly large, the thickness of the adsorbed liquid layer can be closely modeled by BET multilayer adsorption isotherm. Also, the content of the vaporized liquid molecules in the environment surrounding the wafer surface is adjusted by the partial pressure of the vapor in the mixture. The last step, as shown in step 120, the wafer surface bearing the pre-implementing adsorbed liquid layer will be contacted with the plating electrolyte solution. In one embodiment, a bias voltage may be applied to the wafer surface prior to contacting with the electrolyte solution, as shown by an optional step 119, if a electrochemical plating process is used, the optional step 119 of applying a bias voltage is provided before the step 120, otherwise, the step 119 can be omitted. Since the pre-implementing adsorbed layer is very thin, when contacting the wafer surface with the electrolyte solution, dilution from such a thin adsorbed liquid layer to bulk plating electrolyte is minimal even at a high volume setting. For example, the global electrolyte dilution percentage from a 2 nanometer thick adsorbed liquid film is 5,000 times less than a 10 micrometer thick liquid film formed hydrodynamically.

FIG. 1b shows an alternative process for pre-wetting wafer surface for metallization, which uses a different method to vaporize a liquid. In step 132, a liquid, such as de-ionized water is heated. Then in step 134, a carrier gas, such as air, N₂, He, and Ar, is flushed into the heated liquid, then the vapor of the liquid is mixed with the carrier gas to form a vapor mixture. In step 136, the flow rate of the carrier gas is controlled so as to adjust the throughput of the vapor mixture. The pressure of the vapor mixture is controlled (as shown in step 138). For steps 140-150, is the same as the steps 110-120 as mentioned above. That means, in step 140, the temperature of the mixture is maintained. In step 142, the vaporized liquid molecules are delivered to the environment near the wafer surface. In step 144, the bulk air in environment surrounding wafer surface is displaced with the vaporized liquid molecules. In step 146, vaporized liquid molecules are transported from bulk vapor environment onto wafer surface and into patterned structures. In step 148, a pre-implementing adsorbed liquid layer is condensed onto the wafer surface from the vapor environment. In step 150, the wafer surface bearing the pre-implementing adsorbed liquid layer is contacted with the plating electrolyte solution. An optional step 149 is also provided, when electrochemical plating process is used, a bias voltage will be applied. In other embodiment, the step of vaporizing a liquid can be realized by other methods, such as flash evaporation.

The pre-wetting process can be applied to pre-wetting the surface for metallization step from electrolyte solutions in semiconductor device interconnection formation, or fabricating electrical contacts including bump and through silicon via formation for packaging semiconductor devices. According to the different metal ions contained in the electrolytes for different metallization steps, for example, the electrolytes may contain Cu, Au, Ag, Ni, Ru and Co ions for semiconductor device interconnection formation and may contain Cu, Au, Ni, Sn, Pt, and Ag ions for packaging semiconductor devices; the liquid can be different materials. The pre-implementing adsorbed liquid layer on the wafer surface formed by the liquid molecules should be wettable by and miscible with the plating electrolyte solution.

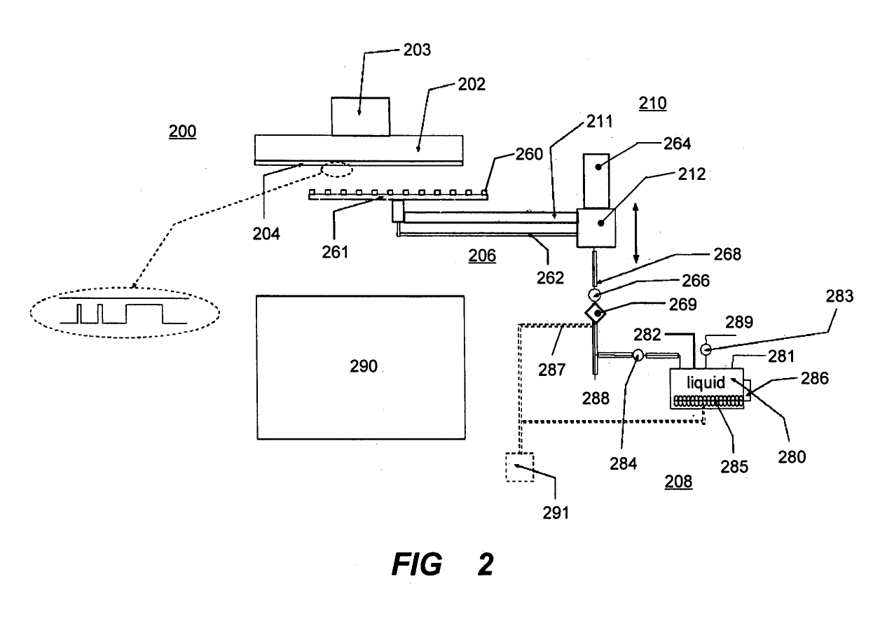

FIG. 2 shows an apparatus for implementing the pre-wetting process mentioned above. The apparatus 200 comprises: a substrate holding device 202 for holding a substrate 204 having one or more features formed thereon. An established layer of metal also covers at least part of the surface of the substrate 204. In one embodiment, the substrate holding device 202 is put in rotational motion by a motor 203. A vapor delivery device 206 sprays vapor that contains at least one type of the molecules to be condensed into a thin pre-implementing adsorbed liquid layer on the substrate surface. As shown in FIG. 2, the vapor delivery device 206 consists of a nozzle or a set of nozzles 260, a tube 262, a position fixer 264, a pressure regulator 266, an insulating wall 268 and a filter 269. The filter 269 is provided before the pressure regulator 266 and insulating wall 268 provides insulation. A mechanical system 210 is also provides, the mechanical system 210 is composed of an actuator 212 and a connect arm 211, which controls the relative motion between the vapor delivery device 206 and the substrate 204. The nozzle 260 is positioned in proximity to the surface of the substrate 204, the nozzle 260 can be either housed in an independent process module or integrated onto an existing processing module, such as the plating module (for example, the discharging plate 261). The thin pre-implementing adsorbed liquid layer can also be formed during wafer transfer by integrating the nozzle 260 onto a wafer transfer robot. In one embodiment, the nozzle 260 can be stationary or put in motion relative to the substrate by an actuator. Continue to see FIG. 2, the apparatus 200 further comprises a vapor generation device 208 that converts part of the liquid into vapor. As shown in FIG. 2, the vapor generation device 208 consists of a vessel 280, a liquid inlet 281, an outlet 282, a pressure release valve 283, a throttle valve 284, a heater 285, a pressure-temperature control loop 286, a carrier gas inlet 287, a liquid drain 288, and an exhaust 289. Vapor is generated by heating the liquid in the vessel 280 with controlled pressure. A dry gas, such as air, N₂, He, and Ar, is used as carrying medium for the vaporized liquid molecules. The dry gas is contained in a dry gas source 291. The dry gas is blown into the liquid inside the vessel and exits at the outlet, carrying the vaporized liquid molecules to pass a pressure regulator before reaching the nozzle. In one embodiment, the pressure release valve 283 is set between 1 and 7 bar and the pressure-temperature control loop is set between 35° C. to 170° C. The vapor delivery lines from vapor generator to nozzles are heat-insulated. The vapor exit outlets on vapor delivery device 260 may have various orientations and size.

The above mentioned components: the set of nozzles 260, the tube 262, and the position fixer 264 can be built on an existing process module, such as be integrated to a metallization module, directly above the plating cell containing electrolyte solutions 290 as shown in FIG. 2.

What is claimed is:

1. A method for pre-wetting wafer surface, comprising:
vaporizing a liquid;
delivering the vaporized liquid molecules to the environment near the wafer surface;
displacing the bulk air in environment surrounding wafer surface with the vaporized liquid molecules and transporting them onto wafer surface and into patterned structures;
condensing a pre-implementing adsorbed liquid layer onto the wafer surface including patterned structures from the vapor environment;
contacting the wafer surface bearing the pre-implementing adsorbed liquid layer with the plating electrolyte solution.

2. The method of claim 1, wherein the liquid that forms the pre-implementing adsorbed liquid layer on the wafer surface is wettable by the plating electrolyte solution.

3. The method of claim 1, wherein the liquid that forms the pre-implementing adsorbed liquid layer on the wafer surface is miscible with the plating electrolyte solution.

4. The method of claim 1, wherein vaporizing the liquid is done by flash evaporation.

5. The method of claim 1, wherein vaporizing the liquid is done by flushing the carrier gas through the liquid.

6. The method of claim 1, wherein the carrier gas is selected from a group of gases:
air, N₂, He, and Ar.

7. The method of claim 1, wherein the transport of the vaporized liquid molecules into the patterned features of vias, trenches and dual damascenes on the wafer surface by a combination of gas phase diffusion and convection.

8. The method of claim 1, wherein the pre-implementing adsorbed liquid layer of nanometer thickness is formed by multilayer adsorption of the vaporized molecules on the wafer surface.

9. The method of claim 1, wherein the content of the vaporized liquid molecules in the environment surrounding the wafer surface is adjusted by the partial pressure of the vapor in the mixture.

10. The method of claim 1, wherein the thickness of the pre-implementing adsorbed liquid layer formed on the wafer surface is controlled by the content of the vaporized liquid molecules in the environment surrounding the wafer surface.

11. The method of claim 1, wherein the thickness of the pre-implementing adsorbed liquid layer formed on the wafer surface is controlled by the temperature difference between the vapor and the wafer surface.

12. The method of claim 1, wherein the pre-implementing adsorbed liquid layer formed at elevated temperature has lower surface tension that the liquid at room temperature.

13. The method of claim 1, wherein the vaporized liquid molecules condense selectively when the wafer surface having partitions of different free surface energy.

14. The method of claim 13, wherein the selective condensation of the pre-implementing adsorbed liquid layer triggers selective nucleation in the subsequent metallization process.

15. The method of claim 1, wherein the method is applied to pre-wetting the surface for metallization step from electrolyte solutions in semiconductor device interconnection formation.

16. The method of claim 15, wherein metal ions in the electrolytes are selected from a group of metal salts: Cu, Au, Ag, Ni, Ru and Co.

17. The method of claim 1., wherein the process is applied to pre-wetting the wafer surface for metallization step from electrolyte solutions during wire and solder formation in packaging semiconductor devices.

18. The method of claim 17, wherein metal ions in the electrolytes are selected from a group of metal salts: Cu, Au, Ni, Sn, Pt, and Ag.

19. The method of claim 1, wherein the process is applied to pre-wetting the wafer surface for metallization step from electrolyte solutions during through the substrate via formation in packing semiconductor devices in stacks.

20. The method of claim 19, wherein metal ions in the electrolytes are selected from a group of metal salts: Cu, Au, Ni, Sn, Pt, and Ag.

21. An apparatus for pre-wetting wafer surface, comprising:
a substrate holding device that holds substrate having one or more features formed thereon, and an established layer of metal covers at least part of the substrate surface;
a vapor delivery device that sprays vapor containing at least one type of the molecules to be condensed into a thin pre-implementing adsorbed liquid layer on the substrate surface;
a vapor generation device that converts part of the liquid into vapor; and
a mechanical system that controls the relative motion between the vapor delivery device and the substrate.

22. The apparatus of claim 21, wherein said substrate holding device, vapor delivery device, and mechanical system are in one enclosed process module.

23. The apparatus of claim 21, wherein said vapor delivery device and mechanical system are integrated to a metallization module.

24. The apparatus of claim 21, where in said vapor delivery device is integrated onto a wafer transfer robot.

25. The apparatus of claim 21, wherein the vapor delivery device consists of a nozzle, a tube, a position fixer, a pressure regulator, and a filter.

26. The apparatus of claim 21, wherein the vapor delivery device is put in motion by an actuator.

27. The apparatus of claim 21, wherein the substrate holding device is put in rotational motion by a motor.

28. The apparatus of claim 21, wherein the vapor generation device consists of a vessel, a liquid inlet, an outlet, a pressure release valve, a throttle valve, a heater, a pressure-temperature control loop, and a carrier gas inlet, a liquid drain, and an exhaust.

29. The apparatus of claim 28, wherein the pressure release valve is set between 1 and 7 bar.

30. The apparatus of claim 28, wherein temperature in the pressure-temperature control loop is set between 35° C. to 170° C.
